(19) United States
(12) Patent Application Publication
(10) Pub. No.: US 2025/0036364 A1
(43) Pub. Date: Jan. 30, 2025

(54) ENTROPY MAINTAINING METHOD FOR TRUE RANDOM NUMBER GENERATOR AND TRUE RANDOM NUMBER GENERATOR THEREOF

(71) Applicant: NUVOTON TECHNOLOGY CORPORATION, HSINCHU CITY (TW)

(72) Inventors: Hui-Chun KO, Zhubei City (TW); Chung Ming HSIEH, Zhubei City (TW)

(21) Appl. No.: 18/406,447

(22) Filed: Jan. 8, 2024

(30) Foreign Application Priority Data
Jul. 28, 2023 (TW) 112128504

(51) Int. Cl. G06F 7/58; H03K 3/03

(52) U.S. Cl. CPC G06F 7/588; H03K 3/0315

(57) ABSTRACT

An entropy maintaining method for a true random number generator and a true random number generator thereof are provided. The true random number generator includes a plurality of first ring oscillation output circuits. The entropy maintaining method includes providing at least one second ring oscillation output circuit in the true random number generator, the at least one second ring oscillation output circuit initially disabled; after the true random number generator is operated, recording logic of generated random bit signals every preset time; counting the logic of the random number bit signal to obtain a statistic value; and determining, according to the statistic value, whether the at least one second ring oscillation output circuit is operated in combination with the plurality of first ring oscillation output circuits to generate the random bit signals.

### CROSS-REFERENCE TO RELATED APPLICATION

This application claims the priority from the TW Patent Application No. 112128504, filed on Jul. 28, 2023, and all contents of such TW Patent Application are included in the present disclosure.

### BACKGROUND

### 1. Field of the Invention

The present disclosure is related to true random number generator technologies, in particular to, an entropy maintaining method for a true random number generator and a true random number generator thereof.

### 2. Description of the Related Art

TRNG, the abbreviation for true random number generator, is a device or algorithm that can physically generate random numbers. The true random number generator generates random numbers by using randomness of physical processes, such as radioactive decay, thermal noise, thermal fluctuations of electronic devices, etc. The random numbers generated by the true random number generator are highly random and unpredictable, and thus are widely used in the fields of cryptography, analog computing, etc. The entropy of a ring oscillator may be applied to the true random number generator because the output sequence of the ring oscillator is random and uncertain. With appropriate processing and filtering, the output sequence of the ring oscillator may be used as a source of the true random number generator.

The size of the entropy of the ring oscillator indicates the degree of randomness and uncertainty of the output sequence of the ring oscillator. The higher entropy value indicates that the output sequence is more random and uncertain. The entropy of the ring oscillator is related to signal jitter. Since the waveform of the output sequence of the ring oscillator is irregular and random, a large amount of clock skew and clock signal jitter exist in the output sequence. The size of the signal jitter depends on the degree of randomness and uncertainty of the internal signal waveform of the ring oscillator. When the entropy of the ring oscillator is higher, the clock skew and clock jitter in the output sequence may be larger.

In order to increase the entropy value of the true random number generator, multiple ring oscillators are adopted. However, using more ring oscillators results in higher power consumption.

### SUMMARY

The present disclosure provides an entropy maintaining method for a true random number generator and a true random number generator thereof, which are used to generate random bit values, maintain entropy values of the generated random bit values, and reduce power consumption.

Embodiments of the present disclosure provide a true random number generator comprising a plurality of first ring oscillation output circuits, at least one second ring oscillation output circuit, a first logic circuit, an output latch circuit, and a storage and control circuit. Each of the plurality of first ring oscillation output circuits receives a first clock signal and outputs a first logic signal based on the first clock signal. When the at least one second ring oscillation output circuit is enabled, the at least one enabled second ring oscillation output circuit receives the first clock signal and outputs a second logic signal based on the first clock signal. The first logic circuit includes a plurality of input terminals and an output terminal, each of the plurality of input terminals is coupled to a corresponding one of the plurality of first ring oscillation output circuits and the at least one second ring oscillation output circuit to receive one of first logic signals and the second logic signal and output a logic output signal. The output latch circuit receives the logic output signal and the first clock signal to sequentially output a random bit signal based on the logic output signal and the first clock signal. The storage and control circuit receives the random bit signals and stores the random bit signals, wherein when an amount of the stored random bit signals reaches a preset number, the storage and control circuit determines whether to enable the at least one second ring oscillation output circuit based on an entropy value of the stored random bit signals.

According to preferred embodiments of the present disclosure, the at least one second ring oscillation output circuit is plural, and when the amount of the stored random bit signals reaches the preset number, one of the plurality of second ring oscillation output circuits is determined whether to be enabled based on the entropy value of the stored random bit signals. In some other preferred embodiments, when the amount of the stored random bit signals reaches the preset number, the amount of the plurality of second ring oscillation output circuits to be enabled is determined based on the entropy value of the stored random bit signals.

According to preferred embodiments of the present disclosure, each of the plurality of first ring oscillation output circuits respectively includes a first ring oscillator and an output terminal. The first ring oscillator includes an output terminal. The first latch circuit includes an input terminal, an output terminal, and a clock terminal, wherein the input terminal of the first latch circuit is coupled to the output terminal of the first ring oscillator, the output terminal of the first latch circuit is coupled to the corresponding one of the output terminals of the first logic circuit, and the clock terminal of the first latch circuit receives the first clock signal.

According to preferred embodiments of the present disclosure, the at least one second ring oscillation output circuit includes a second ring oscillator and a second latch circuit. The second ring oscillator includes an output terminal. The second latch circuit includes an input terminal, an output terminal, and a clock terminal, wherein the input terminal of the second latch circuit is coupled to the output terminal of the second ring oscillator, the output terminal of the second latch circuit is coupled to the corresponding one of the output terminals of the first logic circuit, and the clock terminal of the second latch circuit receives the first clock signal.

According to preferred embodiments of the present disclosure, the storage and control circuit is configured for counting an amount of first logic values of the random bit signals to determine the entropy value of the random bit signal. In some preferred embodiments, the amount of the first logic values of the random bit signals is greater than a first threshold, the storage and control circuit enables the at least one second ring oscillation output circuit, wherein the amount of the first logic values of the random bit signals is less than a second threshold, the storage and control circuit enables the at least one second ring oscillation output circuit.

Embodiments of the present disclosure provide an entropy maintaining method for a true random number generator, the true random number generator comprising a plurality of first ring oscillation output circuits. The entropy maintaining method includes providing at least one second ring oscillation output circuit in the true random number generator, wherein the at least one second ring output circuit is initially disabled; after the true random number generator is operated, recording logic values of random bit signals generated every preset time; counting the logic values of the random bit signal to obtain a statistic value; and determining, based on the statistic value, whether the at least one second ring oscillation output circuit is operated in combination with the plurality of first ring oscillation output circuits to generate the random bit signals.

According to preferred embodiments of the present disclosure, the statistic value is an amount of the logic values of the random bit signals being a first logic value, wherein the entropy value maintaining method further includes: when the amount of the first logic values of the random bit signals is greater than a first threshold, enabling the at least one second ring oscillation output circuit.

According to preferred embodiments of the present disclosure, wherein the at least one second ring oscillation output circuit is plural, wherein the statistic value is an amount of the logic values of the random bit signals being a first logic value, wherein the entropy value maintaining method further includes when the amount of the first logic values of the random bit signals is greater than a first threshold, an amount of the plurality of second ring oscillation output circuits to be enabled is determined according to a difference between the amount of the first logic value and the first threshold.

To sum up, embodiments of the present invention adopt an additional built-in backup ring oscillator, which is not enabled under normal circumstances to save energy. When it is found that the entropy value of the output random bits counted for a period of time does not conform to specifications, the additional built-in backup ring oscillator is enabled to increase the entropy value of the true random number generator and increase the entropy value of the random bits.

To further understand the technology, means, and effects of the present disclosure, reference may be made by the detailed description and drawing as follows. Accordingly, the purposes, features and concepts of the present disclosure can be thoroughly and concretely understood. However, the following detail description and drawings are only used to reference and illustrate the implementation of the present disclosure, and they are not used to limit the present disclosure.

### BRIEF DESCRIPTION OF THE DRAWINGS

The drawings are provided to make the persons with ordinary knowledge in the field of the art further understand the present disclosure, and are incorporated into and constitute a part of the specification of the present disclosure. The drawings illustrate demonstrated embodiments of the present disclosure, and are used to explain the principal of the present disclosure together with the description of the present disclosure.

FIG. 1 is a schematic system block diagram illustrating a true random number generator according to a preferred embodiment of the present disclosure.

FIG. 2 is a schematic flowchart illustrating an entropy maintaining method for a true random number generator according to a preferred embodiment of the present disclosure.

FIG. 3 is a schematic flowchart illustrating sub-steps of the step S205 of the entropy maintaining method according to a preferred embodiment of the present disclosure.

FIG. 4 is a schematic flowchart illustrating sub-steps of the step S205 of the entropy maintaining method according to a preferred embodiment of the present disclosure.

### DESCRIPTION OF THE PREFERRED EMBODIMENTS

Reference will now be made in detail to exemplary embodiments of the present disclosure, which will be illustrated in the accompanying drawings. Where possible, the same reference symbols are used in the drawings and the description to refer to the same or similar components. In addition, the implementation of the exemplary embodiment is only one of the realization ways of the design concept of the present disclosure, and the following examples are not intended to limit the present disclosure.

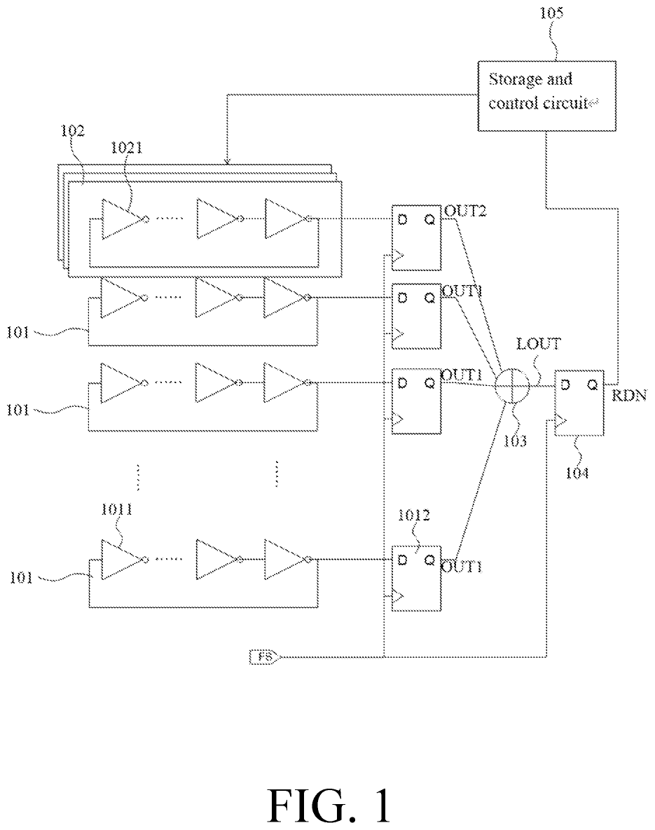

FIG. 1 is a schematic system block diagram illustrating a true random number generator according to a preferred embodiment of the present disclosure. Please refer to FIG. 1, the true random number generator includes a plurality of first ring oscillation output circuits 101, at least one second ring oscillation output circuit 102, a first logic circuit 103, an output latch circuit 104, a storage and control circuit 105, and a clock generation circuit 106. In this embodiment, each first ring oscillation output circuit 101 includes a chain of inverters 1011 and a latch circuit 1012. Those skilled in the art should understand that a ring oscillator does not necessarily use an inverter, but can also use, for example, a ring serial amplifier or other logic gate, and thus the present disclosure is not limited thereto. Furthermore, in order to allow the first ring oscillation output circuit 101 to output its logic based on the clock signal, the output terminal of the first ring oscillation output circuit 101 is additionally coupled to the latch circuit 1012 to synchronously lock the logic output by the chain of inverter string 1011 based on the clock signal. Although the latch circuit 1012 in this embodiment is a D-type flip-flop, those skilled in the art should understand that other latch circuit, such as RS flip-flop, JK flip-flop, and T-type flip-flop, may also be used in this embodiment, and thus the present disclosure is not limited to thereto.

The first ring oscillation output circuit 101 receives a first clock signal FS output by the clock generation circuit 106 and outputs a first logic signal OUT1 based on the first clock signal FS. In addition, in this embodiment, the at least one second ring oscillation output circuit 102 is a backup ring oscillation output circuit. In an initial state, the at least one second ring oscillation output circuit 102 is in a disabled state. Similarly, the at least one second ring oscillation output circuit 102 in this embodiment includes a chain of inverters 1021 and a latch circuit 1022. According to the same reason as stated above, the present disclosure is not limited thereto. When the at least one second ring oscillation output circuit 102 is enabled, the at least one enabled second ring oscillation output circuit 102 also receives the first clock signal FS and outputs a second logic signal OUT2 based on the first clock signal FS.

The first logic circuit 103 includes a plurality of input terminals and an output terminal, each of the plurality of input terminals is coupled to a corresponding one of the plurality of first ring oscillation output circuits 101 and the at least one second ring oscillation output circuit 102 to receive one of first logic signals OUT1 and the second logic signal OUT2 and output a logic output signal LOUT. In this embodiment, the first logic circuit 103 may be implemented by using an exclusive OR gate (XOR). Similarly, the first logic circuit 103 may also be implemented by using other logic circuits, and thus the present disclosure is not limited thereto.

Furthermore, in order to synchronize the output, the output terminal of the first logic circuit 103 is also coupled to the output latch circuit 104. The output latch circuit 104 receives the logic output signal LOUT and the first clock signal FS to sequentially output a random bit signal RDN based on the logic output signal LOUT and the first clock signal FS. The storage and control circuit 105 receives the random bit signals RDN and stores the random bit signals RDN (according to timing). When an amount of the stored random bit signals RDN reaches a preset number, the storage and control circuit 105 determines whether the entropy value of the stored random bit signals RDN conforms to circuit specifications. If the entropy value of the current stored random bit signals RDN still conforms to the specifications, the second ring oscillator output circuit 102 is not enabled. If the entropy value does not conform to the specifications, it represents that the randomness of the output random bit signals RDN is insufficient, and the storage and control circuit 105 enables the second ring oscillator output circuit 102 to increase the entropy value of this true random number generator.

For example, assume that the preset number is 1000 random bit signals RDN, the storage and control circuit 105 sequentially stores 1000 random bit signals RDN. Ideally, out of the 1000 random bit signals RDN, there should be 500 logic “1”s and 500 logic “0” s. However, the actual situation may not be so ideal, and thus upper and lower thresholds are set in this embodiment. Taking logic “1” as an example, the manner of setting the thresholds may be, for example, the amount of logic “1”s, with the upper threshold of 600 and the lower threshold of 400. If the amount of logic “1”s is between 600 and 400, it represents that the entropy value conforms to the specifications. If the amount of logic “1”s is greater than 600 or less than 400, it represents that the entropy value does not conform to the specifications. In this case, the storage and control circuit 105 enables the second ring oscillator output circuit 102 to increase the entropy value of this true random number generator.

Additionally, in the circuit design, different thresholds may be set according to different bit rates. For example, the above threshold setting takes the upper limit 0.6 and the lower limit 0.4 as an example. When the bit rate is 100 times, the threshold setting is adjusted to the upper limit of 0.62 and the lower limit of 0.38. That is, when 1000 random bit signals RDN are sampled, if the amount of logic “1”s is greater than 620 or less than 380, it represents that the entropy value does not conform to the specifications. When the bit rate is 1000 times, the above threshold setting is adjusted to the upper limit of 0.64 and the lower limit of 0.36. That is, when 1000 random bit signals RDN are sampled, if the amount of logic “1”s is greater than 640 or less than 360, it represents that the entropy value does not conform to the specifications.

Furthermore, in another preferred embodiment, multiple threshold ranges may be set, and different numbers of second ring oscillator output circuits 102 may be enabled based on the offset range. For example, the first threshold range is set, for example, as 0.6 to 0.4, the second threshold range is set, for example, as 0.65 to 0.35, and the third threshold range is set, for example, as 0.7 to 0.3. Taking the above embodiment as an example, when 1000 random bit signals RDN are sampled, if the counted amount of logic “1”s is greater than 600 and less than 650, one second ring oscillation output circuit 102 is enabled; if the counted amount of logic “1”s is greater than 650 and less than 700, two second ring oscillation output circuits 102 are enabled; if the counted amount of logic “1”s is greater than 700, three second ring oscillation output circuits 102 are enabled.

Similarly, taking the above embodiment as an example. When 1000 random bit signals RDN are sampled, if the counted amount of logic “1”s is below 400 but above 350, one second ring oscillator output circuit 102 is enabled; if the counted amount of logic “1”s is below 350 but above 300, two second ring oscillator output circuits 102 are enabled; if the counted amount of logic “1”s is below 300, three second ring oscillator output circuits 102 are enabled. The above embodiments are only for illustrative purposes to explain the spirit of the present disclosure and do not necessarily involve the actual setting of three second ring oscillator output circuits 102. Additionally, the threshold values are examples provided to illustrate the spirit of the present disclosure. Designers may perform different settings according to different requirements of products, and the present disclosure is not limited thereto.

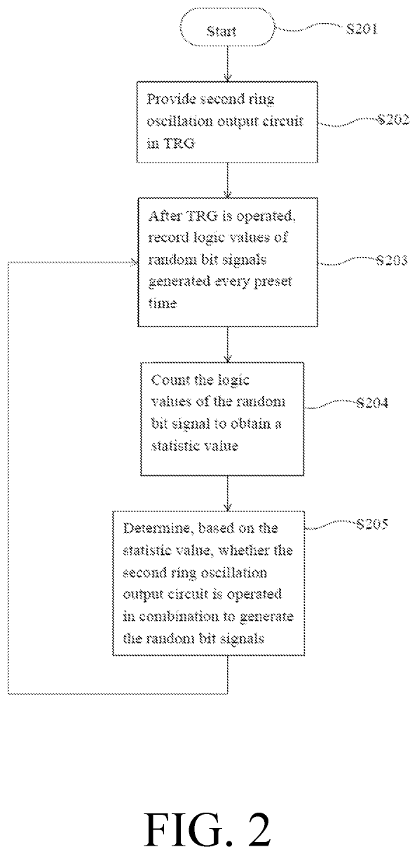

According to the above embodiments, an entropy maintaining method for a true random number generator can be summarized. FIG. 2 is a schematic flowchart illustrating an entropy maintaining method for a true random number generator according to a preferred embodiment of the present disclosure. Please refer to FIG. 2, the entropy maintaining method for the true random number generator includes the following steps:

### Step S201: Start.

Step S202: Provide at least one second ring oscillation output circuit in the true random number generator. The at least one second ring output circuit is initially disabled.

Step S203: After the true random number generator is operated, record logic values of random bit signals generated every preset time.

Step S204: Count the logic values of the random bit signal to obtain a statistic value.

Step S205: Determine, based on the statistic value, whether the at least one second ring oscillation output circuit is operated in combination with the plurality of first ring oscillation output circuits to generate the random bit signals. Return to step S203 to recount.

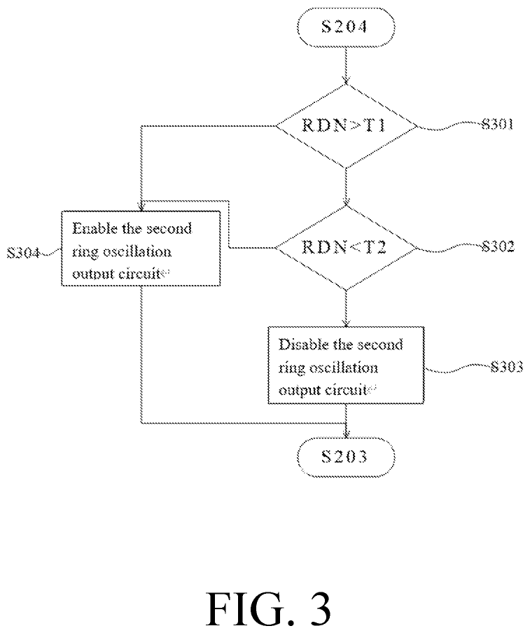

FIG. 3 is a schematic flowchart illustrating sub-steps of the step S205 of the entropy maintaining method according to a preferred embodiment of the present disclosure. Please refer to FIG. 3, the step S205 of the entropy maintaining method includes the following steps:

Step S301: Determine whether the amount of the first logic values of the random bit signals (RDN) is greater than a first threshold (T1). If not, perform step S302. If yes, perform step S304.

Step S302: Determine whether the amount of the first logic values of the random bit signals is less than a second threshold (T2). If not, perform step S303. If yes, perform step S304.

Step S303: Disable the at least one second ring oscillation output circuit. Return to step S203.

Step S304: Enable the at least one second ring oscillation output circuit. Return to step S203.

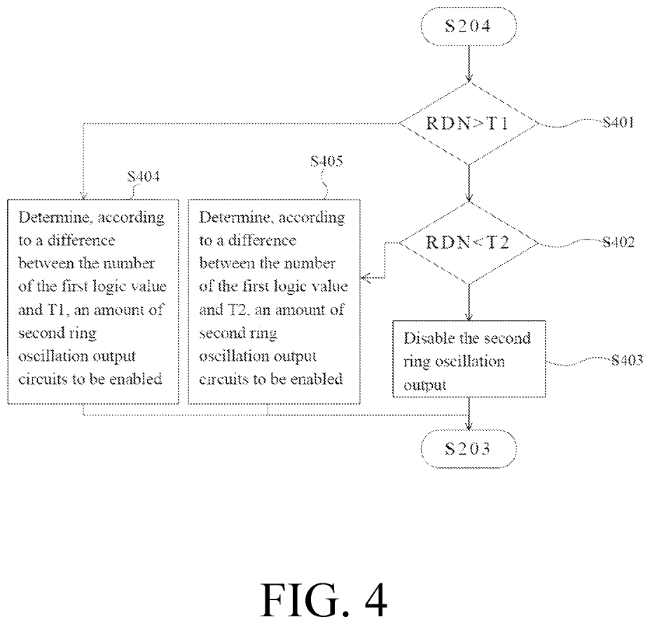

The above embodiment is a technology that has only one set of second ring oscillation output circuits and determines whether to enable the circuits through the threshold value. The one set of second ring oscillation output circuits is not necessarily one second ring oscillation output circuit. In another embodiment, there is an example of setting multiple thresholds and multiple sets of second ring oscillation output circuits. FIG. 4 is a schematic flowchart illustrating sub-steps of the step S205 of the entropy maintaining method according to a preferred embodiment of the present disclosure. Please refer to FIG. 4, the step S205 of the entropy maintaining method includes the following steps:

Step S401: Determine whether the amount of the first logic values of the random bit signals (RDN) is greater than a first threshold (T1). If the amount of the first logic values of the random bit signals is less than the first threshold, perform step S402. If the amount of the first logic values of the random bit signals is greater than the first threshold, it represents that the entropy value does not conform to specifications, perform step S404.

Step S402: Determine whether the amount of the first logic values of the random bit signals (RDN) is less than a second threshold (T2). If the amount of the first logic values of the random bit signals is greater than the second threshold, perform step S403. If the amount of the first logic values of the random bit signal sis less than the second threshold, it represents that the entropy value does not conform to the specifications, perform step S405.

Step S403: Disable the at least one second ring oscillation output circuit. Return to step S203.

Step S404: Determine, according to a difference between the amount of the first logic value and the first threshold, an amount of the plurality of second ring oscillation output circuits to be enabled. Follow the above embodiment that sets multiple threshold ranges and enables, based on the offset range, different numbers of second ring oscillation circuits 102.

Step S405: Determine, according to a difference between the amount of the first logic value and the second threshold, an amount of the plurality of second ring oscillation output circuits to be enabled. Follow the above embodiment that sets multiple threshold ranges and enables, based on the offset range, different numbers of second ring oscillation circuits 102.

To sum up, embodiments of the present invention adopt an additional built-in backup ring oscillator, which is not enabled under normal circumstances to save energy. When it is found that the entropy value of the output random bits counted for a period of time does not conform to specifications, the additional built-in backup ring oscillator is enabled to increase the entropy value of the true random number generator and increase the entropy value of the random bits. Since the backup ring oscillator is only enabled when the entropy value is insufficient, power consumption may be reduced.

It should be understood that the examples and the embodiments described herein are for illustrative purpose only, and various modifications or changes in view of them will be suggested to those skilled in the art, and will be included in the spirit and scope of the application and the appendix with the scope of the claims.

What is claimed is:

1. A true random number generator, comprising:
a plurality of first ring oscillation output circuits, wherein each of the plurality of first ring oscillation output circuits receives a first clock signal and outputs a first logic signal based on the first clock signal;
at least one second ring oscillation output circuit, wherein when the at least one second ring oscillation output circuit is enabled, the at least one enabled second ring oscillation output circuit receives the first clock signal and outputs a second logic signal based on the first clock signal;
a first logic circuit comprising a plurality of input terminals and an output terminal, each of the plurality of input terminals is coupled to a corresponding one of the plurality of first ring oscillation output circuits and the at least one second ring oscillation output circuit to receive one of first logic signals and the second logic signal and output a logic output signal;
an output latch circuit configured for receiving the logic output signal and the first clock signal to sequentially output a random bit signal based on the logic output signal and the first clock signal; and
a storage and control circuit configured for receiving the random bit signals and storing the random bit signals, wherein when an amount of the stored random bit signals reaches a preset number, the storage and control circuit determines whether to enable the at least one second ring oscillation output circuit based on an entropy value of the stored random bit signals.

2. The true random number generator according to claim 1, wherein the at least one second ring oscillation output circuit is plural, and:
when the amount of the stored random bit signals reaches the preset number, one of the plurality of second ring oscillation output circuits is determined whether to be enabled based on the entropy value of the stored random bit signals.

3. The true random number generator according to claim 1, wherein the at least one second ring oscillation output circuit is plural,
and when the amount of the stored random bit signals reaches the preset number, the amount of the plurality of second ring oscillation output circuits to be enabled is determined based on the entropy value of the stored random bit signals.

4. The true random number generator according to claim 1, wherein each of the plurality of first ring oscillation output circuits further comprises:
a first ring oscillator comprising an output terminal; and
a first latch circuit comprising an input terminal, an output terminal, and a clock terminal, wherein the input terminal of the first latch circuit is coupled to the output terminal of the first ring oscillator, the output terminal of the first latch circuit is coupled to the corresponding one of the output terminals of the first logic circuit, and the clock terminal of the first latch circuit receives the first clock signal.

5. The true random number generator according to claim 1, wherein the at least one second ring oscillation output circuit further comprises:
a second ring oscillator comprising an output terminal; and
a second latch circuit comprising an input terminal, an output terminal, and a clock terminal, wherein the input terminal of the second latch circuit is coupled to the output terminal of the second ring oscillator, the output terminal of the second latch circuit is coupled to the corresponding one of the output terminals of the first logic circuit, and the clock terminal of the second latch circuit receives the first clock signal.

6. The true random number generator according to claim 1, wherein the storage and control circuit is configured for counting an amount of first logic values of the random bit signals to determine the entropy value of the random bit signals.

7. The true random number generator according to claim 6, wherein the amount of the first logic values of the random bit signals is greater than a first threshold, the storage and control circuit enables the at least one second ring oscillation output circuit, wherein the amount of the first logic values of the random bit signals is less than a second threshold, the storage and control circuit enables the at least one second ring oscillation output circuit.

8. An entropy maintaining method for a true random number generator, the true random number generator comprising a plurality of first ring oscillation output circuits, and the entropy maintaining method comprising:
providing at least one second ring oscillation output circuit in the true random number generator, wherein the at least one second ring output circuit is initially disabled;
after the true random number generator is operated, recording logic values of random bit signals generated every preset time;
counting the logic values of the random bit signal to obtain a statistic value; and
determining, based on the statistic value, whether the at least one second ring oscillation output circuit is operated in combination with the plurality of first ring oscillation output circuits to generate the random bit signals.

9. The entropy maintaining method according to claim 8, wherein the statistic value is a amount of the logic values of the random bit signals being a first logic value, and the entropy value maintaining method further comprises:
when the amount of the first logic values of the random bit signals is greater than a first threshold, enabling the at least one second ring oscillation output circuit.

10. The entropy maintaining method according to claim 8, wherein the at least one second ring oscillation output circuit is plural,
wherein the statistic value is an amount of the logic values of the random bit signals being a first logic value, wherein the entropy value maintaining method further comprises:
when the amount of the first logic value of the random bit signal is greater than a first threshold, an amount of the plurality of second ring oscillation output circuits to be enabled is determined according to a difference between the amount of the first logic value and the first threshold.
